(19) United States
(12) Patent Application Publication
(10) Pub. No.: US 2026/0344212 A1
(43) Pub. Date: Oct. 29, 2026

(54) DISPLAY DEVICE AND ELECTRONIC DEVICE INCLUDING THE DISPLAY DEVICE

(71) Applicant: Samsung Display Co., LTD., Yongin-si (KR)

(72) Inventor: Tae Kon KIM, Yongin-si (KR)

(21) Appl. No.: 19/386,658

(22) Filed: Nov. 12, 2025

(30) Foreign Application Priority Data
Apr. 24, 2025 (KR) 10-2025-0053811

(51) Int. Cl. H10K 59/131

(52) U.S. Cl. CPC H10K 59/131

(57) ABSTRACT

A display device includes: a substrate including a display area and a non-display area adjacent to the display area; at least one first power line provided in the non-display area, extending in a first direction, and connected to pixels located in the display area; and at least one second power line extending in a second direction intersecting the first direction and located adjacent to an end of the at least one first power line. The at least one first power line includes a first pattern spaced apart from the at least one second power line in the first direction; and a second pattern electrically connected to the first pattern and being relatively closer to the at least one second power line than the first pattern. The first pattern and the second pattern include different respective materials.

This application claims priority to Korean Patent Application No. 10-2025-0053811, filed on Apr. 24, 2025, and all the benefits accruing therefrom under 35 U.S.C. §119, the content of which in its entirety is herein incorporated by reference.

### BACKGROUND

### 1. Field

Embodiments of the present disclosure generally relate to a display device and an electronic device including the display device.

### 2. Description of the Related Art

With the development of information technology, the importance of a display device as a connection medium between a user and information has become increasingly important. In response to this, the use of display devices such as a liquid crystal display device and an organic light emitting display device is increasing.

During a manufacturing process of the display device, static electricity may be introduced into an internal circuit of a display panel. The introduced static electricity may damage electrical elements in the display panel. In particular, in a display panel having an irregular round shape, static electricity introduced into a power line to which driving power is supplied may damage pixels.

The above disclosure is intended solely to aid in the understanding of the background art of the technical ideas of the present disclosure and is not to be construed as constituting prior art known to those skilled in the art of the present disclosure.

### SUMMARY

Embodiments provide a display device and an electronic device including the display device, which can improve the reliability. For example, in a display device having an irregular round shape, it is possible to prevent (or reduce) static electricity from flowing into a power line, thereby improving pixel defects.

In accordance with an embodiment of the invention, a display device includes: a substrate including a display area and a non-display area adjacent to the display area; at least one first power line provided in the non-display area, extending in a first direction, and connected to pixels located in the display area; and at least one second power line extending in a second direction intersecting the first direction and located adjacent to an end of the at least one first power line. The at least one first power line includes: a first pattern spaced apart from the at least one second power line in the first direction; and a second pattern electrically connected to the first pattern and being relatively closer to the at least one second power line than the first pattern. The first pattern and the second pattern include different respective materials.

In an embodiment, the pixels may have a stepped arrangement at an edge of the display area.

In an embodiment, the first pattern may include a metallic material, and the second pattern may include a conductive material.

In an embodiment, the at least one first power line may be electrically connected to a bus line which supplies a first driving power.

In an embodiment, the at least one first power line may overlap a portion of the bus line.

In an embodiment, an end of the bus line may be floating at an edge of the non-display area.

In an embodiment, the at least one first power line may further include at least one insulating layer between the first pattern and the second pattern, and the at least one insulating layer may have at least one first contact hole connecting the first pattern and the second pattern.

In an embodiment, an end of the first pattern may be connected to the second pattern via the at least one first contact hole, and another end of the first pattern may be connected to the bus line via at least one second contact hole different from the at least one first contact hole.

In an embodiment, the at least one second contact hole may be relatively further spaced apart from the at least one second power line than the at least one first contact hole in the first direction.

In an embodiment, the display device may further include at least one data line extending in the first direction and disposed adjacent to the at least one first power line in the second direction.

In an embodiment, the at least one data line may include a third pattern spaced apart from the at least one second power line in the first direction; and a fourth pattern electrically connected to the third pattern and relatively closer to the at least one second power line than the third pattern, and the third pattern and the fourth pattern may include different respective materials.

In an embodiment, the third pattern may include a metallic material, and the fourth pattern may include a conductive material.

In an embodiment, the third pattern and the fourth pattern may be electrically connected via at least one third contact hole.

In accordance with an embodiment of the invention, an electronic device includes: a processor; and a display device which displays an image according to a control of the processor. The display device includes a substrate including a display area and a non-display area adjacent to the display area; at least one first power line provided in the non-display area, extending in a first direction, and connected to pixels located in the display area; and at least one second power line extending in a second direction intersecting the first direction and located adjacent to an end of the at least one first power line. The at least one first power line includes a first pattern spaced apart from the at least one second power line in the first direction; and a second pattern electrically connected to the first pattern and being relatively closer to the at least one second power line than the first pattern. The first pattern and the second pattern include different respective materials.

In an embodiment, the pixels may have a stepped arrangement at an edge of the display area.

In an embodiment, the first pattern may include a metallic material, and the second pattern may include a conductive material.

In an embodiment, the at least one first power line may be electrically connected to a bus line which supplies a first driving power.

In an embodiment, the at least one first power line may further include at least one insulating layer between the first pattern and the second pattern, and the at least one insulating layer may have at least one first contact hole connecting the first pattern and the second pattern.

In an embodiment, an end of the first pattern may be connected to the second pattern via the at least one first contact hole, and another end of the first pattern may be connected to the bus line via at least one second contact hole different from the at least one first contact hole.

In an embodiment, the at least one second contact hole may be relatively further spaced apart from the at least one second power line than the at least one first contact hole in the first direction.

### BRIEF DESCRIPTION OF THE DRAWINGS

The above and other features of embodiments of the present disclosure will become more apparent by describing in further detail embodiments thereof with reference to the accompanying drawings, in which:

FIG. 1 is a perspective view schematically illustrating a display device in accordance with an embodiment of the invention.

FIG. 2 is a block diagram illustrating a display device in accordance with an embodiment of the invention.

FIG. 3 is a block diagram illustrating any one of pixels of FIG. 2 in accordance with an embodiment of the invention.

FIG. 4 is a plan view illustrating a display panel of FIG. 2 in accordance with an embodiment of the invention.

FIG. 5 is an enlarged view illustrating area A of FIG. 4 in accordance with an embodiment of the invention.

FIG. 6 is an enlarged view illustrating area B of FIG. 4 in accordance with an embodiment of the invention.

FIG. 7 is a cross-sectional view along line I-I' of FIG. 6 in accordance with an embodiment of the invention.

FIG. 8 is a plan view illustrating lines of FIG. 6 in accordance with an embodiment of the invention.

FIG. 9 is an enlarged view illustrating area B' of FIG. 4 in accordance with an embodiment of the invention.

FIG. 10 is a plan view illustrating lines of FIG. 9 in accordance with an embodiment of the invention.

FIG. 11 is a block diagram illustrating an electronic device in accordance with an embodiment of the invention.

FIG. 12 is a schematic diagram of an electronic device in accordance with embodiments of the present disclosure.

### DETAILED DESCRIPTION

Hereinafter, a preferred embodiment according to the present disclosure is described in detail with reference to the accompanying drawings. It should be understood that the following description describes those portions supportive of understanding the operation according to the present disclosure, and that other portions may be omitted in order not to obscure the essence of the present disclosure. Furthermore, the present disclosure is not limited to the embodiments described herein and may be embodied in other forms. However, the embodiments described herein are provided to illustrate the technical ideas of the present disclosure in sufficient detail to facilitate practice by one having ordinary skill in the technical field to which the present disclosure belongs.

Throughout the specification, when a part is “connected” to another part, this may include not only a case where the part is “directly connected” but also a case where it is “indirectly connected” with another element interposed therebetween. The terminology used herein is for the purpose of describing particular embodiments and is not intended to limit the invention. Throughout the specification, when it is said that a part may “include” a component, this may mean that other components may be further included, rather than excluding other components, unless otherwise specified. “At least one of X, Y, and Z”, and “at least one selected from the group consisting of X, Y and Z”, may be interpreted as one X, one Y, one Z, or any combination of two or more of X, Y or Z (e.g., XYZ, XY, YZ, ZX). Here, “and/or” may include all combinations of one or more of the corresponding configurations.

As used herein, terms such as first, second, and the like may be used to describe various components, but such components are not limited to such terms. These terms are used to distinguish one component from another. Thus, a first component may refer to a second component without departing from what is disclosed herein.

Spatially relative terms such as "below," "above," and the like may be used for purposes of description, and in so doing describe the relationship of one element or feature to another element(s) or feature(s) as depicted in the drawings. Spatially relative terms are intended to include, in addition to the orientations depicted in the drawings, different orientations in use, operation, and/or manufacture. For example, when a device illustrated in the drawings is inverted, elements depicted as being located "below" other elements or features are oriented "above" other elements or features. Thus, in an embodiment, the term "below" may include both up and down directions. Furthermore, the device may be oriented in other directions (e.g., rotated 90 degrees or otherwise), and spatially relative terms used herein are to be interpreted accordingly.

Various embodiments are described with reference to the drawings, which illustrate example embodiments. Accordingly, it is to be expected that the geometries may vary, for example, due to tolerances and/or manufacturing techniques. Accordingly, the embodiments disclosed herein should not be construed as limited to the particular geometries illustrated, but should be construed to include changes in geometry that occur, for example, as a result of manufacturing. As such, the shapes illustrated in the drawings may not represent the actual shapes of the regions of the device, and the embodiments are not limited thereto.

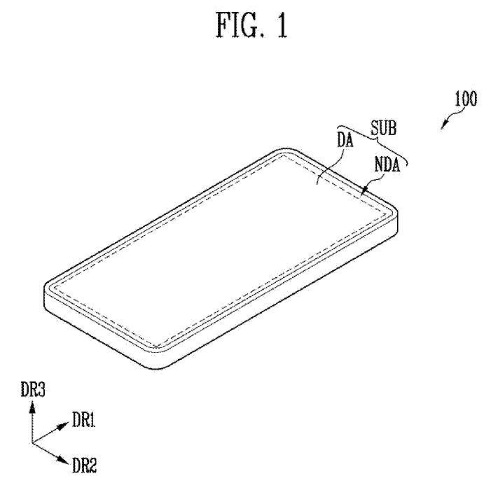

FIG. 1 is a perspective view schematically illustrating a display device in accordance with an embodiment of the invention.

Referring to FIG. 1, a display device 100 may include a display area DA and a non-display area NDA. The display area DA may be an area that displays an image, and the non-display area NDA may be provided on the periphery of the display area DA. The non-display area NDA may be an area where an image is not displayed. According to an embodiment, the shape of the display area DA and the shape of the non-display area NDA may be designed to be relative.

The display device 100 may be provided in a variety of shapes, for example, as a rectangular plate having two pairs of sides parallel to each other, but embodiments are not limited thereto. For a case in which the display device 100 is provided as a rectangular plate, either of the two pairs of sides may be provided with one pair of sides being longer than the other pair of sides. In FIG. 1, the display device 100 is illustrated as having rounded edges where one long side and one short side abut, but embodiments are not limited thereto. For example, the display device DD may have angled edges that are straight lines.

In an embodiment of the present disclosure, for ease of illustration, the display device 100 is illustrated in a rectangular shape having a pair of long sides and a pair of short sides, an extension direction of the long sides may be expressed as a first direction DR1, an extension direction of the short sides may be expressed as a second direction DR2, and a direction perpendicular to the long sides and the short sides may be expressed as a third direction DR3. The first to third directions DR1, DR2, and DR3 may refer to directions indicated by the first to third directions DR1, DR2, and DR3, respectively.

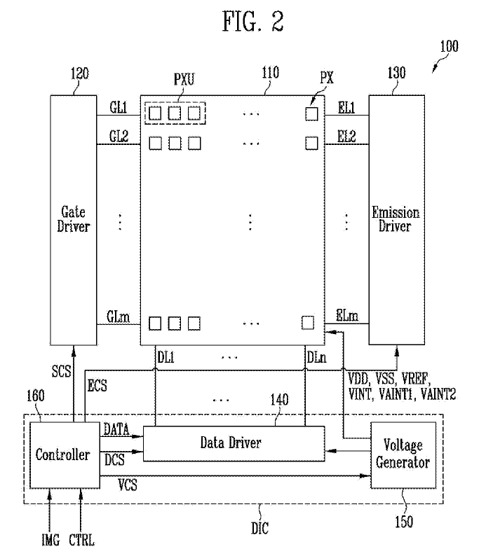

FIG. 2 is a block diagram illustrating a display device in accordance with an embodiment of the invention.

Referring to FIG. 2, the display device 100 may include a display panel 110, a gate driver 120, an emission driver 130, a data driver 140, a voltage generator 150, and a controller 160.

The display panel 110 may include pixels PX. The pixels PX may be connected to a gate driver 120 via first to m-th gate lines GL1 to GLm. The pixels PX may be connected to the emission driver 130 via first to m-th emission control lines EL1 to ELm. The pixels PX may be connected to the data driver 140 via first to n-th data lines DL1 to DLn.

Each of the pixels PX may include at least one light emitting element configured to generate light. Accordingly, each of the pixels PX may generate light in one of a variety of colors, such as red, green, blue, cyan, magenta, yellow, and the like. Two or more of the pixels PX may comprise a single pixel unit PXU. For example, as illustrated in FIG. 2, three pixels may comprise a single pixel unit PXU.

The gate driver 120 may be connected to pixels arranged in a row direction via the first to m-th gate lines GL1 to GLm. The pixels arranged in a row direction may comprise a pixel row, and the gate driver 120 may be connected to the pixel row via a gate line. The gate driver 120 may output a scan signal to the first to m-th gate lines GL1 to GLm in response to a scan control signal SCS. In embodiments, each gate line may include a plurality of sub-gate lines, and sub-scan signals may be output through the plurality of sub-gate lines. In such cases, the scan signal may be understood to include the sub-scan signals. In embodiments, the scan control signal SCS may include clock signals and a scan start signal indicating the start of each frame.

The emission driver 130 may be connected to the pixels arranged in a row direction via the first to m-th emission control lines EL1 to ELm. The emission driver 130 may be connected to the pixel row via an emission control line. The emission driver 130 may output a light emission control signal to the first to the m-th emission control lines EL1 to ELm in response to an emission control signal ECS. Each emission control line may include a plurality of sub-emission control lines, and sub-emission control signals may be output via the plurality of sub-emission control lines. In such cases, the light emission control signal may be understood to include the sub-light emission control signals. In embodiments, the emission control signal ECS may include clock signals and an emission start signal indicating the start of each frame.

The gate driver 120 may be located on one side of the display panel 110, and the emission driver 130 may be located on another side of the display panel 110 opposite the one side of the display panel 110. However, embodiments are not limited thereto. The gate driver 120 and the emission driver 130 may be disposed around the periphery of the display panel 110 in various configurations, depending on the embodiment.

The data driver 140 may be connected to the pixels arranged in a column direction via the first to n-th data lines DL1 to DLn. The pixels arranged in a column direction may comprise a pixel column, and the data driver 140 may be connected to the pixel column via a data line. The data driver 140 may receive image data DATA and a data control signal DCS from the controller 160. The data driver 140 may operate in response to the data control signal DCS. In embodiments, the data control signal DCS may include clock signals, a start pulse, and the like.

The data driver 140 may apply data voltages (or data signals) having grayscale values corresponding to the image data DATA to the first to n-th data lines DL1 to DLn using voltages from the voltage generator 150. In an example in which a scan signal is applied to each of the first to m-th gate lines GL1 to GLm, data voltages corresponding to the image data DATA may be applied to the first to n-th data lines DL1 to DLn. Accordingly, the corresponding pixels PX may emit light corresponding to the data voltages, and the image may be displayed on the display panel 110.

The voltage generator 150 may be operable in response to a voltage control signal VCS from the controller 160. The voltage generator 150 may be configured to generate a plurality of voltages and provide the generated voltages to components of the display device 100. For example, the voltage generator 150 may be configured to generate the plurality of voltages by receiving an input voltage from external to the display device 100, regulating the received voltage, and regulating the regulated voltage.

The voltage generator 150 may generate a first driving power VDD, a second driving power VSS, a reference power VREF, a first initialization power VINT, a second initialization power VAINT1, and a third initialization power VAINT2, and the first driving power VDD, the second driving power VSS, the reference power VREF, the first initialization power VINT, the second initialization power VAINT1, and the third initialization power VAINT2 may be provided to the pixels PX. However, embodiments are not limited thereto. For example, at least one among the first driving power VDD, the second driving power VSS, the reference power VREF, the first initialization power VINT, the second initialization power VAINT1, and the third initialization power VAINT2 may be provided by an external device of the display device 100.

The first driving power VDD may have a relatively high voltage level. The second driving power VSS may have a lower voltage level than the first driving power VDD. For example, the second driving power VSS may have a negative voltage level. The first initialization power VINT may have a voltage level between the first driving power VDD and the second driving power VSS, have the same voltage level as the second driving power VSS, or have a voltage level lower than the second driving power VSS.

The controller 160 may control various operations of the display device 100. The controller 160 may receive input image data IMG and a control signal CTRL to control the input image data IMG from an external source. In response to the control signal CTRL, the controller 160 may generate the scan control signal SCS, the emission control signal ECS, the data control signal DCS, and the voltage control signal VCS.

The controller 160 may convert the input image data IMG to be suitable for the display device 100 or the display panel 110 and output the image data DATA to the data driver 140. For example, the controller 160 may arrange the input image data IMG according to an arrangement of pixels PX to output the image data DATA.

Two or more components of the data driver 140, voltage generator 150, and controller 160 may be mounted on a single integrated circuit. As illustrated in FIG. 1, the data driver 140, voltage generator 150, and controller 160 may be included in a driver integrated circuit DIC. In such cases, the data driver 140, voltage generator 150, and controller 160 may be functionally distinct components within a single driver integrated circuit DIC. In other embodiments, at least one of the data driver 140, voltage generator 150, and controller 160 may be provided as a component separate from the driver integrated circuit DIC.

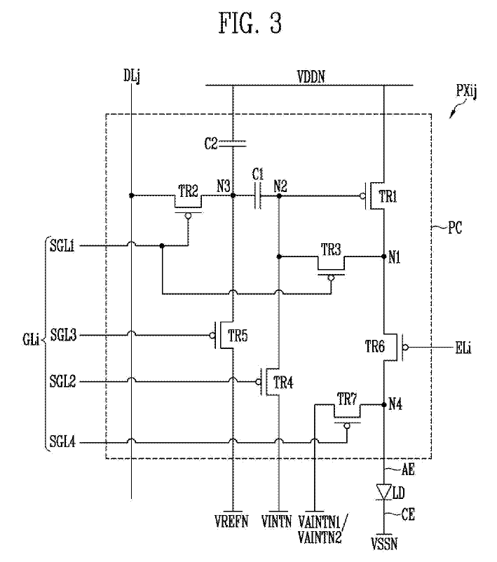

FIG. 3 is a block diagram illustrating any one of pixels of FIG. 2 in accordance with an embodiment of the invention.

In FIG. 3, a pixel PXij of the pixels PX of FIG. 2 arranged in an i-th row (where i-th is an integer greater than or equal to 1 and less than or equal to m) and in a j-th column j-th (where j-th is an integer greater than or equal to 1 and less than or equal to n) is illustrated by way of example.

Referring to FIGS. 2 and 3, the pixel PXij may include a pixel circuit PC and a light emitting element LD.

The light emitting element LD may include an anode electrode AE, a cathode electrode CE, and a light emitting layer. The light emitting layer may be physically disposed between the anode electrode AE and the cathode electrode CE. The light emitting layer may be configured to emit light in response to an amount of current flowing from the anode electrode AE through the light emitting layer to the cathode electrode CE. The anode electrode AE of the light emitting element LD may be electrically connected to a first driving power node VDDN via the pixel circuit PC. The cathode electrode CE of the light emitting element LD may be electrically connected to a second driving power node VSSN. The light emitting element LD may emit light according to the amount of current flowing from the first driving power node VDDN to the second driving power node VSSN through the pixel circuit PC.

The light emitting element LD may include an organic light emitting diode. However, embodiments are not limited thereto. For example, the light emitting element LD may include an inorganic light emitting diode. For example, the light emitting element LD may be a light emitting element including both organic and inorganic materials. In FIG. 3, a pixel PXij is illustrated as including a single light emitting element LD, but the pixel PXij may include two or more light emitting elements. In such a case, the two or more light emitting elements may be connected to each other in series or in parallel.

The pixel circuit PC may be connected to an i-th gate line GLi of the first to m-th gate lines GL1 to GLm of FIG. 2, an i-th emission control line ELi of the first to m-th emission control lines EL1 to ELm of FIG. 2, and a j-th data line DLj of the first to n-th data lines DL1 to DLn of FIG. 2. The pixel circuit PC may be configured to control the light emitting element LD according to signals received via these signal lines.

The i-th gate line GLi may include first to fourth sub-gate lines SGL1 to SGL4. The pixel circuit PC may operate in response to first to fourth sub-scan signals received via the first to fourth sub-gate lines SGL1 to SGL4. The pixel circuit PC may include first to seventh transistors TR1 to TR7, and first and second capacitors C1 and C2. However, embodiments are not limited thereto. The pixel circuit PC may be implemented in any of various forms of circuits including a plurality of transistors and one or more capacitors. For example, the pixel circuit PC may include two transistors and one capacitor. Depending on the embodiment of the pixel circuit PC, the number of sub-gate lines included in the i-th gate line GLi and the number of sub-emission control lines included in the i-th emission control line ELi may be variable. The first to seventh transistors TR1 to TR7 may be P-type transistors. Each of the first to seventh transistors TR1 to TR7 may be a metal oxide silicon field effect transistor (MOSFET). However, embodiments are not limited thereto. For example, at least one of the first to seventh transistors TR1 to TR7 may be replaced with an N-type transistor.

In embodiments, the first to seventh transistors TR1 to TR7 may include amorphous silicon semiconductors, monocrystalline silicon, polycrystalline silicon, oxide semiconductors, and the like.

The first transistor TR1 may be connected between the first driving power node VDDN and a first node N1. The first transistor TR1 may include a drain electrode connected to the first node N1, a source electrode connected to the first driving power node VDDN, and a gate electrode connected to a second node N2. The first transistor TR1 may turn on in response to a voltage difference between the drain electrode and the source electrode. The first driving power node VDDN may be provided with the first driving power VDD of FIG. 2. The second driving power node VSSN may be provided with the second driving power VSS of FIG. 2. The second driving power VSS may have a lower level than the first driving power VDD. In an example in which the first transistor TR1 and the sixth transistor TR6 are turned on, the first transistor TR1 may control the amount of current flowing from the first driving power node VDDN to the second driving power node VSSN through the light emitting element LD according to a voltage difference between the first and second nodes N1 and N2.

The second transistor TR2 may be connected between the data line DLj and a third node N3. A gate electrode of the second transistor TR2 may be connected to the first sub-gate line SGL1. The second transistor TR2 may turn on when a first sub-scan signal of agate-on voltage is applied to the first sub-gate line SGL1, thereby electrically connecting the data line DLj and the third node N3. Accordingly, a data voltage of the data line DLj may be delivered to the third node N3.

The third transistor TR3 may be connected between the first node N1 and the second node N2. A gate electrode of the third transistor TR3 may be connected to the first sub-gate line SGL1. The third transistor TR3 may turn on when the first sub-scan signal of the gate-on voltage is applied to the first sub-gate line SGL1, thereby electrically connecting the first node N1 and the second node N2.

The fourth transistor TR4 may be connected between the second node N2 and a first initialization power node VINTN. A gate electrode of the fourth transistor TR4 may be connected to the second sub-gate line SGL2. The fourth transistor TR4 may turn on when a second sub-scan signal of a gate-on voltage is applied to the second sub-gate line SGL2, thereby connecting the second node N2 to the first initialization power node VINTN. The first initialization power node VINTN may be provided with the first initialization power VINT of FIG. 2. Accordingly, when the fourth transistor TR4 is turned on, the first initialization power VINT may be delivered to the second node N2.

The fifth transistor TR5 may be connected between a reference power node VREFN and the third node N3. A gate electrode of the fifth transistor TR5 may be connected to the third sub-gate line SGL3. The fifth transistor TR5 may turn on when a third sub-scan signal of the gate-on voltage is applied to the third sub-gate line SGL3, thereby electrically connecting the third node N3 to the reference power node VREFN. The reference power node VREFN may be provided with the reference power VREF of FIG. 2. Accordingly, the reference power VREF may be delivered to the third node N3 when the fifth transistor TR5 is turned on.

The sixth transistor TR6 may be connected between the first node N1 and a fourth node N4. Here, the fourth node N4 may be an anode electrode AE of the light emitting element LD. A gate electrode of the sixth transistor TR6 may be connected to the emission control line ELi. The sixth transistor TR6 may turn on when a light emission control signal of a gate-on voltage is applied to the emission control line ELi.

The seventh transistor TR7 may be connected between the fourth node N4 and a second initialization power node VAINTN1 (or a third initialization power node VAINTN2). A gate electrode of the seventh transistor TR7 may be connected to the fourth sub-gate line SGL4. The seventh transistor TR7 may turn on when a fourth sub-scan signal of a gate-on voltage is applied to the fourth sub-gate line SGL4, thereby connecting the anode electrode AE to the second initialization power node VAINTN1 (or the third initialization power node VAINTN2). The seventh transistor TR7 may be connected to either of the second and third initialization power nodes VAINTN1 and VAINTN2 depending on a pixel. The second initialization power node VAINTN1 may be provided with the second initialization power VAINT1 of FIG. 1. The third initialization power node VAINTN2 may be provided with the third initialization power VAINT2 of FIG. 1. Accordingly, when the seventh transistor TR7 is turned on, the second initialization power VAINT (or the third initialization power VAINT2) may be delivered to the anode electrode AE.

The first capacitor C1 may be connected between the second node N2 and the third node N3. The first capacitor C1 or the third node N3, which is one end of the first capacitor C1, may store the data voltage provided via the data line DLj. Further, the second capacitor C2 may be connected between the third node N3 and the first driving power node VDDN.

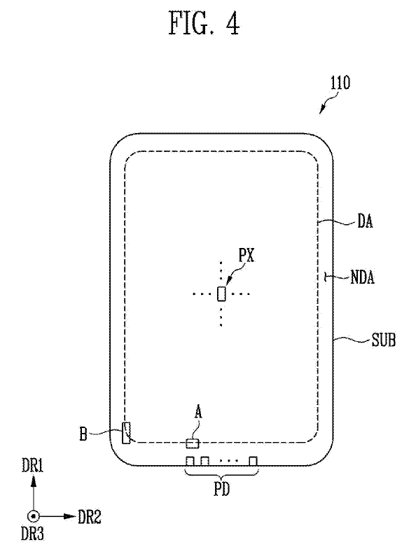

FIG. 4 is a plan view illustrating a display panel of FIG. 2 in accordance with an embodiment of the invention.

Referring to FIGS. 2 and 4, the display panel 110 of FIG. 2 may include a substrate SUB, pixels PX, and pads PD.

The substrate SUB may have a roughly rectangular shape. The substrate may include a pair of long sides parallel to each other in a first direction DR1 and a pair of short sides parallel to each other in a second direction DR2. However, the shape of the substrate SUB is not limited thereto and may have a variety of shapes.

For a case in which the substrate SUB has straight sides, at least some of edges of each shape may be curved. For example, in cast that the substrate SUB has a rectangular shape, a part where adjacent straight sides meet may be replaced by a curve having a preset curvature. In particular, at the lower side of the substrate SUB, the substrate SUB may have various shapes, such as semicircles and semi-ellipses, including straight and curved sides. For example, the substrate SUB may have the shape of a polygon, a circle, a semicircle, an ellipse, and the like.

The substrate SUB may include a display area DA and a non-display area NDA located around the periphery of the display area DA. The display area DA may have various shapes, such as semicircles and semi-ellipses that include straight and curved sides. For example, the display area DA may have a shape corresponding to the substrate SUB.

The pixels PX may be arranged in the display area DA on the substrate SUB. The pixels PX may be arranged in a matrix form along the first direction DR1 and the second direction DR2 intersecting the first direction DR1. However, embodiments are not limited thereto. For example, the pixels PX may be arranged in a zigzag pattern along the first direction DR1 and the second direction DR2. For example, the pixels PX may be arranged in a PENTILE^{TM} shape.

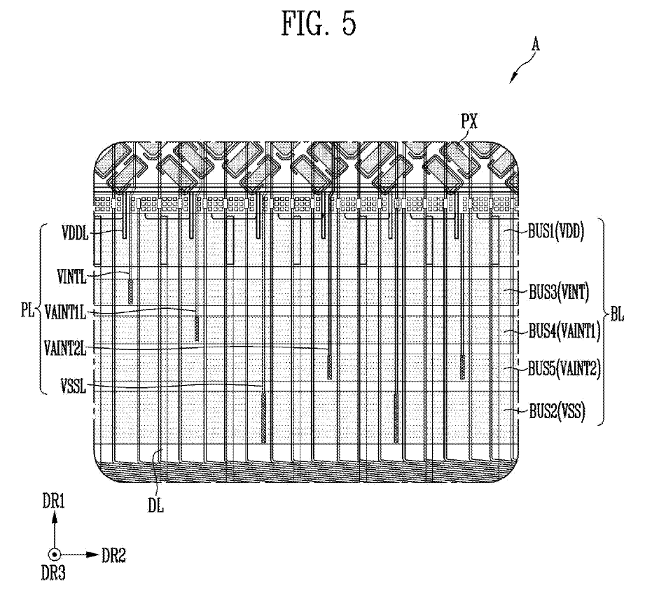

In the non-display area NDA on the substrate SUB, components for controlling the pixels PX may be arranged. For example, wiring associated with the pixels PX, such as the first to m-th gate lines GL1 to GLm, the first to n-th data lines DL1 to DLn, and the first to m-th emission control lines EL1 to ELm of FIG. 2 may be arranged in the non-display area NDA. In some aspects, power bus lines BL (see FIG. 5) and power lines PL (see FIG. 5) providing power such as the first driving power VDD, the second driving power VSS, the reference power VREF, the first initialization power VINT, the second initialization power VAINT1, and the third initialization power VAINT2 of FIG. 2 may be arranged in the non-display area NDA.

In the non-display area NDA on the substrate SUB, pads PD may be located. The pads PD may be electrically connected to the pixels PX via the wiring. For example, the pads PD may be connected to the pixels PX via the first to n-th data lines DL1 to DLn.

The pads PD may interface the display panel 110 to other components of the display device 100. In embodiments, voltages and signals supportive of operation of the components included in the display panel DP may be provided through the pads PD from the driver integrated circuit DIC of FIG. 2. For example, the first to n-th data lines DL1 to DLn may be connected to the driver integrated circuit DIC via the pads PD. For example, the first and second driving powers VDD and VSS may be received from the driver integrated circuit DIC through the pads PD. For example, for a case in which the gate driver 120 is mounted on the display panel DP, the scan control signal SCS may be transmitted to the gate driver 120 via the pads PD from the driver integrated circuit DIC.

In embodiments, a circuit board may be electrically connected to the pads PD using a conductive adhesive, such as an anisotropic conductive film. Here, the circuit board may be a flexible circuit board (FPCB) or a flexible film having a flexible material. The driver integrated circuit DIC may be mounted on the circuit board and electrically connected to the pads PD.

FIG. 5 is an enlarged view illustrating area A of FIG. 4 in accordance with an embodiment of the invention.

Referring to FIGS. 4 and 5, in the display panel 110, power lines PL and power bus lines BL may be arranged in the non-display area NDA. The power bus lines BL may carry power to the power lines PL. The power bus lines BL may provide power to the pixels PX via the power lines PL.

The power bus lines BL may include a first bus line BUS1, a second bus line BUS2, a third bus line BUS3, a fourth bus line BUS4, and a fifth bus line BUS5. The power lines PL may include a first driving power line VDDL, a second driving power line VSSL, a first initialization power line VINTL, a second initialization power line VAINT1L, and a third initialization power line VAINT2L. For example, the first bus line BUS1 may carry the first driving power VDD to the first driving power line VDDL. A second bus line BUS2) may carry a second driving power VSS to a second driving power line VSSL. The third bus line BUS3 may carry the first initialization power VINT to the first initialization power line VINTL. The fourth bus line BUS4 may carry the second initialization power VAINT1 to the second initialization power line VAINT1L. The fifth bus line BUS5 may carry the third initialization power VAINT2 to the third initialization power line VAINT2L.

The power bus lines BL may be arranged on a lower side of the display panel 110. And, the power lines PL electrically connecting the power bus lines BL and the pixels PX may be arranged on a lower side of the display panel 110. For example, at the lower side of the display panel 110, the power bus lines BL may be spaced apart from each other in the first direction DR1. At the lower side of the display panel 110, the power bus lines BL may extend in the second direction DR2. At the lower side of the display panel 110, the power lines PL may be spaced apart from each other in the second direction DR2. At the lower side of the display panel 110, the power lines PL may extend in the first direction DR1. Further, the power lines PL may overlap the power bus lines BL.

The data lines DL may be disposed at the lower side of the display panel 110. For example, at the lower side of the display panel 110, the data lines DL may extend in the first direction DR1. The data lines DL may be arranged adjacent to at least one of the power lines PL in the second direction DR2. Further, the data lines DL may overlap the power bus lines BL.

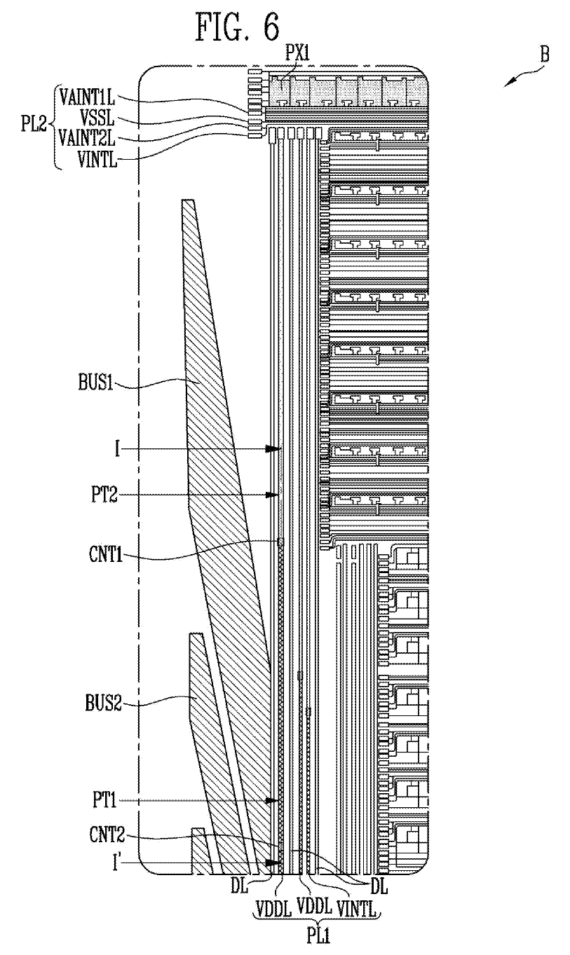

FIG. 6 is an enlarged view illustrating area B of FIG. 4 in accordance with an embodiment of the invention.

Referring to FIGS. 4 and 6, the display panel 110 may include first pixels PX1 having a stepped arrangement at an edge of the display area DA. As a lower side of the display panel 110 has a rounded shape, the first pixels PX1 may be stepped from the edge of the display area DA to follow a curvature of the display area DA. For example, the number of pixels included in a pixel column and a pixel row at the edge of the display area DA may be different for each row and each column. For example, the number of pixels included in a pixel column may be the same or fewer in a direction closer to the edge of the display area DA. The number of pixels included in a pixel row may be the same or fewer in a direction closer to the edge of the display area DA. Thus, the arrangement of the first pixels PX1 may include steps in a form of stairs.

The first pixels PX1 may be electrically connected to at least one data line DL extending in the first direction DR1 and at least one first power line PL1. For example, the first pixels PX1 may be electrically connected to a first driving power line VDDL and a first initialization power line VINTL extending in the first direction DR1. Further, the first pixels PX1 may be electrically connected to a data line DL extending in the first direction DR1. In this case, the data line DL may be arranged adjacent to at least one of the first driving power line VDDL and the first initialization power line VINTL in the second direction DR2.

The first pixels PX1 may overlap at least one second power line PL2 extending in the second direction DR2. The at least one second power line PL2 may be adjacent to an end of the at least one data line DL and an end of the at least one first power line PL1. In this case, the end of the at least one data line DL and the end of the at least one first power line PL1 may be adjacent to the first pixels PX1. For example, the first initialization power line VINTL, the second initialization power line VAINT1L, the third initialization power line VAINT2L, and the second driving power line VSSL extending in the second direction DR2 may be adjacent to an end of the first driving power line VDDL and an end of the first initialization power line VINTL extending in the first direction DR1.

The at least one first power line PL1 may be electrically connected to the at least one bus line BUS1 or BUS2 . The at least one first power line PL1 may overlap a portion of the at least one bus line BUS1 or BUS2. For example, the first driving power line VDDL may be electrically connected to the first bus line BUS1 which supplies the first driving power VDD. The first driving power line VDDL and the first bus line BUS1 may cross each other, and the first driving power line VDDL may overlap a portion of the first bus line BUS1. The first driving power line VDDL may be electrically connected to the first bus line BUS1 via at least one second contact hole CNT2. Further, the first initialization power line VINTL may be electrically connected with the second bus line BUS2 which supplies the first initialization power VINT. The first initialization power line VINTL and the second bus line BUS2 may cross each other, and the first initialization power line VINTL may overlap a portion of the second bus line BUS2.

At least one of the at least one bus line BUS1 or BUS2 may be floating at the edge of the non-display area NDA. As the lower side of the display panel 110 has a rounded shape, the at least one bus line BUS1 or BUS2 arranged at the lower side of the display panel 110 may be electrically disconnected from the edge of the non-display area NDA. Accordingly, the at least one bus line BUS1 or BUS2, which is floated, may be electrically unstable. For example, the at least one bus line BUS1 or BUS2, which is floated, may be easily affected by externally generated potential differences or electrical interference, which may cause voltage spikes or sudden voltage changes.

For example, for a case in which a second contact hole CNT2 is formed which electrically connects the first driving power line VDDL and the first bus line BUS1, there may be a relatively high potential for electrostatic discharge (ESD) to be transmitted through the first driving power line VDDL. For example, an unstable voltage generated on the first bus line BUS1, which is floated, may cause electrostatic discharge (ESD) at an electrical contact such as the second contact hole CNT2. The induced electrostatic discharge (ESD) may be transferred through the second contact hole CNT2 to the first driving power line VDDL, which may overheat and damage the pixels PX.

According to embodiments, the first driving power line VDDL may include a first pattern PT41 and a second patternPT4T2 having a different material from the first pattern PT1. The first pattern PT1 may be spaced apart in the first direction DR1 from the at least one second power line PL2 extending in the second direction DR2. The first pattern PT1 may include a metallic material. The second pattern PT2 may be electrically connected to the first pattern PT1 and may be relatively closer to the at least one second power line PL2 than the first pattern PT1. The second pattern PT2 may be electrically connected to the first pattern PT1 via at least one first contact hole CNT1. The second pattern PT2 may include a conductive material having a relatively lower conductivity than the first pattern PT1.

As such, in the first driving power line VDDL where electrostatic discharge (ESD) is likely to be transmitted, by placing the second pattern PT2 having a different material from the first pattern PT1 forming the second contact hole CNT2, a sufficient separation distance between the first pattern PT1 and the at least one second power line PL2 may be secured. Accordingly, electrostatic discharge (ESD) transmitted to the at least one second power line PL2 via the first driving power line VDDL extending in the first direction DR1 may be minimized, thereby preventing damage to the pixels PX.

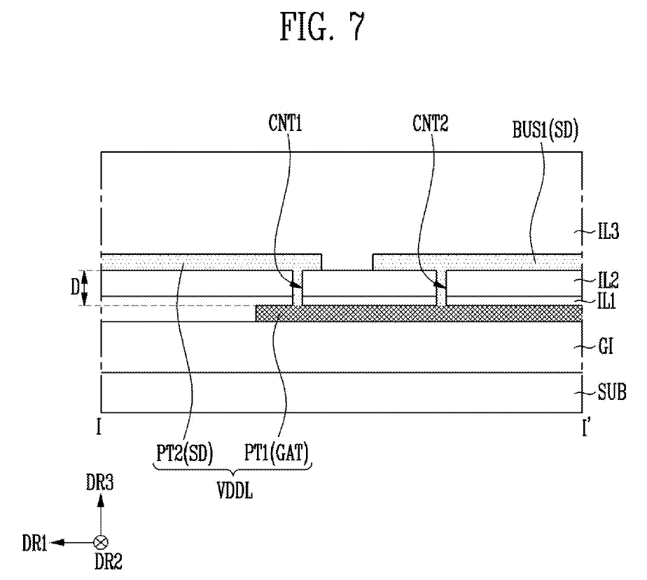

FIG. 7 is a cross-sectional view along line I-I' of FIG. 6 in accordance with an embodiment of the invention.

Referring to FIGS. 4, 6 and 7, the display panel 110 may include the first driving power line VDDL electrically connecting the first pixels PX1 and the first bus line BUS1. For example, at the lower side of the display panel 110, the first driving power line VDDL may be formed in a multi-layer structure. The first driving power line VDDL may include a first pattern PT1 and a second pattern PT2 disposed in different layers.

The following describes the structure in which the components included in the first driving power line VDDL are stacked.

A gate insulating layer GI may be disposed on the substrate SUB. The gate insulating layer GI may be formed such that the gate insulating layer GI covers an active pattern (not illustrated). The gate insulating layer GI may have a single-layer or multi-layer structure including an inorganic insulator. For example, the inorganic insulator may include, but is not limited to, silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂).

The first pattern PT1 of the first driving power line VDDL may be disposed on the gate insulating layer GI. For example, the first pattern PT1 may include the same metallic material as a material used to form a gate electrode GAT. For example, the first pattern PT1 may include, but is not limited to, indium zinc oxide (InZnO), zinc (Zn), magnesium (Mg), aluminum (Al), gold (Au), titanium (Ti), and the like.

A first insulating layer IL1 may be disposed on the first pattern PT1. The first insulating layer IL1 may be disposed such that the first insulating layer IL1 covers the first pattern PT1. The first insulating layer IL1 may have a single-layer or multi-layer structure including an inorganic insulator. For example, the inorganic insulator may include, but is not limited to, silicon oxide (SiOₓ), silicon nitride (SiNₓ), silicon oxynitride (SiOₓN_{y}), aluminum oxide (Al₂O₃), titanium oxide (TiO₂), and the like.

One or more insulating layers may be disposed on the first insulating layer IL1. In FIG. 7, a second insulating layer IL2 is illustrated disposed on the first insulating layer IL1, but is not limited thereto. The second insulating layer IL2 may include, but is not limited to, silicon oxide (SiOₓ), silicon nitride (SiNₓ), silicon oxynitride (SiOₓN_{y}), aluminum oxide (Al₂O₃), titanium oxide (TiO₂), and the like.

On the second insulating layer IL2, the second pattern PT2 and the first bus line BUS1 connected to the first pattern PT1 may be disposed. And, the second pattern PT2 and the first bus line BUS1 may be disposed in the same layer. The second pattern PT2 may include the same material as the first bus line BUS1. For example, the second pattern PT2 may include the same conductive material as a material used to form source and drain electrodes SD. For example, the second pattern PT2 may include, but is not limited to, titanium/aluminum/titanium (Ti/Al/Ti), indium tin oxide (ITO), titanium nitride (TiN), indium oxide (In₂O₃), and the like.

As a thickness D of the first and second insulating layers IL1 and IL2 increases, a capability of the first and second insulating layers IL1 and IL2 for withstanding an electrostatic discharge (ESD) voltage may be improved. For example, as the thickness D between the first pattern PT1 and the second pattern PT2 connected to the first pattern PT1 increases, the electrostatic discharge (ESD) generated by the formation of the second contact hole CNT2 may be further blocked from being transmitted to the second pattern PT2. By increasing the thickness D between the first pattern PT1 and the second pattern PT2 connected to the first pattern PT1, the electrostatic discharge (ESD) transmitted to the second pattern PT2 may be reduced.

A third insulating layer IL3 may be disposed on the second pattern PT2 and the first bus line BUS1. The third insulating layer IL3 may be disposed such that the third insulating layer IL3 covers the second pattern PT2 and the first bus line BUS1. The third insulating layer IL3 may have a single-layer or multi-layer structure including an inorganic insulator. For example, the inorganic insulator may include, but is not limited to, silicon oxide (SiOₓ), silicon nitride (SiNₓ), silicon oxynitride (SiOₓN_{y}), aluminum oxide (Al₂O₃), titanium oxide (TiO₂), and the like.

The first pattern PT1 may be respectively connected to the second pattern PT2 and the first bus line BUS1 via first and second contact holes CNT1 and CNT2 penetrating the first and second insulating layers IL1 and IL2. An end of the first pattern PT1 may be connected to the second pattern PT2 via at least one first contact hole CNT1. Another end of the first pattern PT1 may be connected to the first bus line BUS1 via at least one second contact hole CNT2.

FIG. 7 illustrates an example of the first power line PL1 extending from in the first direction DR1 at the lower side of the display panel 110, and the first initialization power line VINTL may have the same multi-layer structure as the first driving power line VDDL. Therefore, a description thereof is omitted.

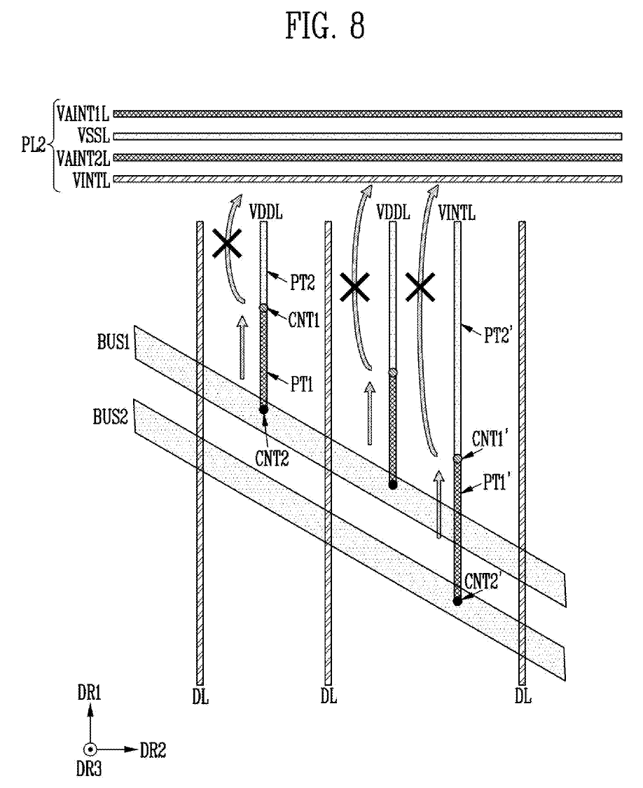

FIG. 8 is a plan view illustrating lines of FIG. 6 in accordance with an embodiment of the invention.

Referring to FIG. 8, in the first driving power line VDDL, an end of the first pattern PT1 may be electrically connected to the first bus line BUS1 carrying the first driving power VDD (see FIG. 2). And, another end of the first pattern PT1 may be electrically connected to the second pattern PT2 having a different material from the first pattern PT1.

For example, the first pattern PT1 of the first driving power line VDDL and the first bus line BUS1 disposed in different layers may be connected via the second contact hole CNT2. For a case in which the second contact hole CNT2 is formed such that the second contact hole CNT2 electrically connects the first driving power line VDDL and the first bus line BUS1, the second contact hole CNT2 may provide a path for electrostatic discharge (ESD) to be transmitted as the second contact hole CNT2 includes a metallic material. The electrostatic discharge (ESD) generated by the formation of the second contact hole CNT2 may be transferred to the first pattern PT1 of the first driving power line VDDL through the second contact hole CNT2 along the metallic material.

The first pattern PT1 of the first driving power line VDDL may extend from the first bus line BUS1 to the first direction DR1 for a preset length. Then, at a preset point thereafter, the first pattern PT1 may be changed to the second pattern PT2 having a different material. The first pattern PT1 may be connected via the first contact hole CNT1 to the second pattern PT2 disposed in a different layer from the first pattern PT1. For example, the first pattern PT1 of the first driving power line VDDL may be disposed in the same layer as the second and third initialization power lines VAINT1L and VAINT2L extending in the second direction DR2. Further, the second pattern PT2 of the first driving power line VDDL may be disposed in the same layer as the first bus line BUS1 and the second driving power line VSSL extending in the second direction DR2. However, embodiments are not limited thereto.

The second contact hole CNT2 may be further spaced apart in the first direction DR1 from the at least one second power line PL2 relative to the first contact hole CNT1. Accordingly, the first pattern PT1 may be further spaced apart in the first direction DR1 from the at least one second power line PL2 extending in the second direction DR2 than the second pattern PT2. As such, by changing the first driving power line VDDL from the first pattern PT1 to the second pattern PT2, a sufficient separation distance between the first pattern PT1 and the at least one second power line PL2 may be secured. For example, for a case in which a second contact hole CNT2 is formed which electrically connects the first driving power line VDDL and the first bus line BUS1, electrostatic discharge (ESD) may be transmitted to the first pattern PT1 of the first driving power line VDDL through the second contact hole CNT2 along a metallic material. In contrast, for example, the electrostatic discharge (ESD) may not be transferred to the second pattern PT2, which has a different material from the first pattern PT1. Accordingly, in the first driving power line VDDL, the path of electrostatic discharge (ESD) transfer to the at least one second power line PL2 along the metallic material may be blocked by arranging the second pattern PT2 having a material different from the first pattern PT1 forming the second contact hole CNT2. The first driving power line VDDL may be implemented with a structure that is robust against electrostatic discharge (ESD). Thus, by minimizing the electrostatic discharge (ESD) transmitted through the first driving power line VDDL extending in the first direction DR1, damage to the first pixels PX1 (see FIG. 6) having a stepped arrangement at the edge of the display area DA (see FIG. 4) of the plurality of pixels PX (see FIG. 4) may be prevented.

Referring to FIG. 8, in the first initialization power line VINTL, an end of a first pattern PT1’ may be electrically connected to the second bus line BUS2 carrying the first initialization power VINT (see FIG. 2). And, another end of the first pattern PT1' may be electrically connected to a second pattern PT2' having a different material from the first pattern PT1'.

For example, the first pattern PT1’ of the first initialization power line VINTL and the second bus line BUS2 disposed in different layers may be connected via a second contact hole CNT2'. The first pattern PT1' of the first initialization power line VINTL may extend from the second bus line BUS2 in the first direction DR1 for a preset length. At a preset point thereafter, the first pattern PT1' may be changed to the second pattern PT2' having a different material. The first pattern PT1' may be connected via a first contact hole CNT1' to the second pattern PT2' disposed in a different layer from the first pattern PT1'. Accordingly, by changing the first initialization power line VINTL from the first pattern PT1’ to the second pattern PT2', a sufficient separation distance between the first pattern PT1’ and the at least one second power line PL2 may be secured. This may block the path for electrostatic discharge (ESD) to be transferred to the at least one second power line PL2. The first initialization power line VINTL may be implemented with a structure that is robust against electrostatic discharge (ESD). Thus, the electrostatic discharge (ESD) transmitted through the first initialization power line VINTL extending in the first direction DR1 may be minimized, thereby preventing damage to the pixels PX.

However, while FIG. 8 illustrates the first driving power line VDDL and the first initialization power line VINTL as an example, embodiments are not limited thereto. For example, at a lower side of the display panel 110, the power lines extending in the first direction DR1 and connecting to the pixels in a stepped arrangement at the edge of the display area may be configured similarly to the first driving power line VDDL.

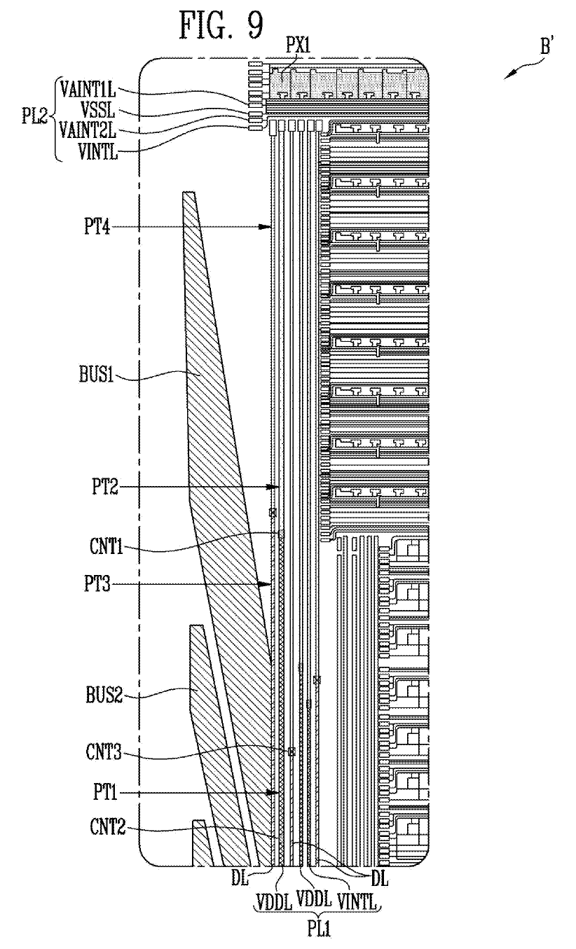

FIG. 9 is an enlarged view illustrating area B' of FIG. 4 in accordance with an embodiment of the invention.

Referring to FIGS. 4 and 9, the display panel 110 may include at least one first power line PL1, at least one second power line PL2, and at least one bus line BUS1 or BUS2.

The first driving power line VDDL and the first initialization power line VINTL may be configured similarly to the first driving power line VDDL and the first initialization power line VINTL of FIG. 6.

The at least one second power line PL2 may be adjacent to an end of the at least one data line DL and an end of the at least one first power line PL1. In this case, the end of the at least one data line DL and the end of the at least one first power line PL1 may be adjacent to the first pixels PX1. For example, the first initialization power line VINTL extending in the second direction DR2, the second initialization power line VAINT1L, the third initialization power line VAINT2L, and the second driving power line VSSL may be adjacent to the end of the at least one data line DL extending in the first direction DR1.

The at least one data line DL may extend in the first direction DR1 and may be disposed adjacent to the at least one first power line PL1 in the second direction DR2. Accordingly, electrostatic discharge (ESD) transmitted to the first pattern PT1 of the first driving power line VDDL via the second contact hole CNT2 may be transmitted to the at least one data line DL disposed adjacent thereto. The electrostatic discharge (ESD) may be transmitted through the at least one data line DL extending in the first direction DR1 and may overheat and damage the pixels PX.

According to embodiments, the at least one data line DL may include a third pattern PT3 and a fourth pattern PT4 having a different material from the third pattern PT3. The third pattern PT3 may be spaced apart in the first direction DR1 from the at least one second power line PL2 extending in the second direction DR2. The third pattern PT3 may include a metallic material. The fourth pattern PT4 may be electrically connected to the third pattern PT3 and may be relatively closer to the at least one second power line PL2 than the third pattern PT3. The fourth pattern PT4 may be electrically connected to the third pattern PT3 via at least one third contact hole CNT3. The fourth pattern PT4 may include a conductive material having a relatively lower conductivity than the third pattern PT3.

In this way, in the data line DL disposed adjacent to the first driving power line VDDL where electrostatic discharge (ESD) is likely to be transmitted, a sufficient separation distance between the third pattern PT3 and the at least one second power line PL2 may be secured by arranging the fourth pattern PT4 having a different material from the third pattern PT3. Accordingly, electrostatic discharge (ESD) transmitted to the at least one second power line PL2 via the at least one data line DL extending in the first direction DR1 may be minimized, thereby preventing damage to the pixels PX.

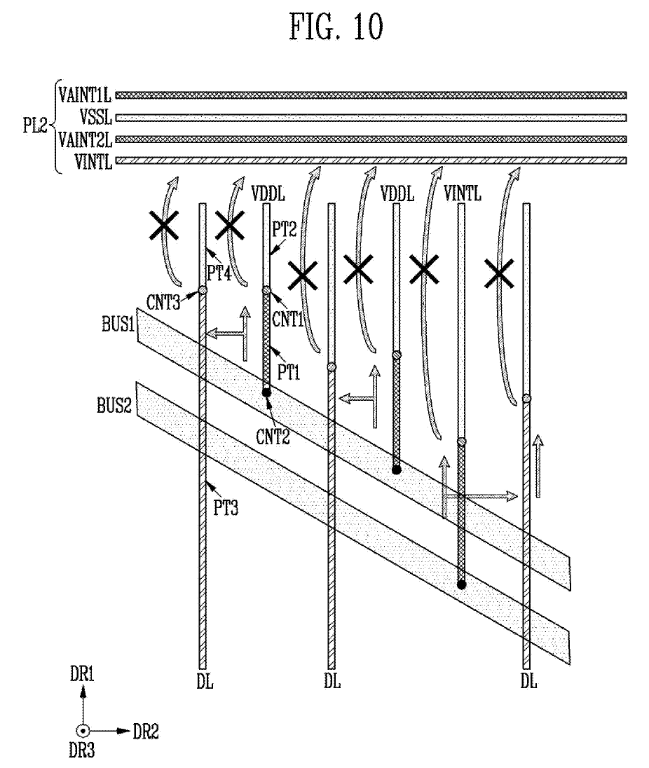

FIG. 10 is a plan view illustrating lines of FIG. 9 in accordance with an embodiment of the invention.

Referring to FIGS. 9 and 10, the display panel 110 may include a first driving power line VDDL, a first initialization power line VINTL, at least one data line DL, at least one second power line PL2, and at least one bus line BUS1 or BUS2.

The first driving power line VDDL, the first initialization power line VINTL, the at least one second power line PL2, and the at least one bus line BUS1 or BUS2 may be configured similarly to the first driving power line VDDL, the first initialization power line VINTL, the at least one second power line PL2, and the at least one bus line BUS1 or BUS2 of FIG. 8.

Referring to FIG. 10, the data line DL may include a third pattern PT3 and a fourth pattern PT4 having a different material from the third pattern PT3. For example, the third pattern PT3 may include a metallic material that is the same as a material used to form a gate electrode. The fourth pattern PT4 may include the same conductive material as a material used to form source and drain electrodes, such as the second pattern PT2 of the first driving power line VDDL.

For example, the third pattern PT3 and the fourth pattern PT4 of the data line DL disposed in different layers may be connected via a third contact hole CNT3. The third pattern PT3 of the data lines DL may extend in the first direction DR1 for a preset length. At a preset point thereafter, the third pattern PT3 may be changed to the fourth pattern PT4 having a different material. The third pattern PT3 may be connected via the third contact hole CNT3 to the fourth pattern PT4 disposed in a different layer from the third pattern PT3. For example, the third pattern PT3 of the data line DL may be disposed in the same layer as the first initialization power line VINTL extending in the second direction DR2. Further, the fourth pattern PT4 of the data line DL may be disposed on the same layer as the second pattern PT2 of the first driving power line VDDL and the second driving power line VSSL extending in the second direction DR2. However, embodiments are not limited thereto.

The third pattern PT3 may be a pattern disposed adjacent to the first pattern PT1 of the first driving power line VDDL. And, the third pattern PT3 may be spaced further in the first direction DR1 than the fourth pattern PT4 from the at least one second power line PL2 extending in the second direction DR2. In this way, by changing the data line DL from the third pattern PT3 to the fourth pattern PT4, a sufficient separation distance between the third pattern PT3 and the at least one second power line PL2 may be obtained. For example, electrostatic discharge (ESD) may be transferred from the first pattern PT1 of the first driving power line VDDL to the third pattern PT3 of the data line DL. In contrast, for example, the electrostatic discharge (ESD) may not be transferred to the fourth pattern PT4, which has a different material from the third pattern PT3. Accordingly, in the data line DL, the path of electrostatic discharge (ESD) transmission to the at least one second power line PL2 along the metallic material may be blocked by arranging the fourth pattern PT4 having a different material from the third pattern PT3. The data line DL may be implemented with a structure that is robust against electrostatic discharge (ESD). Thus, the electrostatic discharge (ESD) transmitted through the data line DL extending in the first direction DR1 may be minimized, thereby preventing damage to the pixels PX (see FIG. 4).

The display device according to an embodiment may be applied to various electronic devices. An electronic device according to an embodiment includes the display device described herein and may further include modules or devices having other additional functions in addition to the display device.

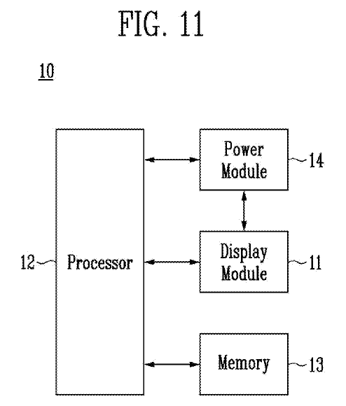

FIG. 11 is a block diagram illustrating an electronic device in accordance with an embodiment of the invention.

Referring to FIG. 11, the electronic device 10 according to an embodiment may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller.

The memory 13 may store data information supportive of the operation of the processor 12 or the display module 11. In an example in which the processor 12 executes an application stored in the memory 13, image data signals and/or input control signals are delivered to the display module 11, and the display module 11 may process the received signals to output image information via the display screen.

The power module 14 may include a power supply module, such as a power adapter or a battery unit, and a power conversion module that converts power supplied by the power supply module to generate power supportive of operation of the electronic device 10.

At least one of each of the configurations described herein of the electronic device 10 may be included within the display device according to the embodiments described herein. Furthermore, some of the individual modules that are functionally contained within one module may be included within the display device and others may be provided separately from the display device. For example, the display device may include the display module 11, while the processor 12, the memory 13, and the power module 14 may be provided in the form of other devices within the electronic device 10 other than the display device.

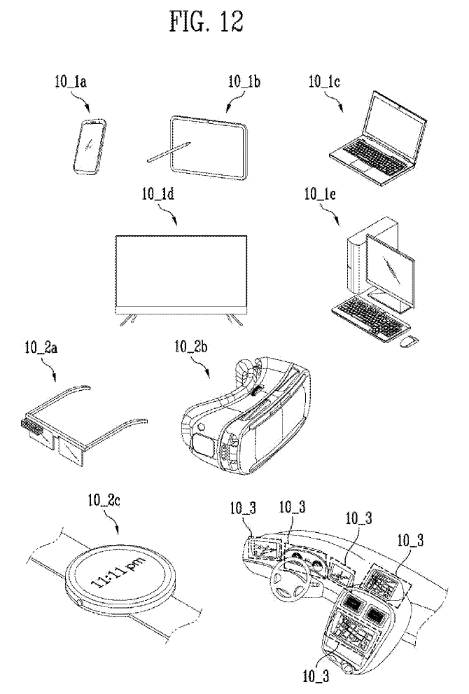

FIG. 12 is a schematic diagram of an electronic device in accordance with embodiments of the present disclosure.

Referring to FIG. 12, various electronic devices with display devices according to embodiments include electronic devices for displaying images, such as a smartphone 10_1a, a tablet PC 10_1b, a laptop 10_1c, a television 10_1d, a desk monitor 10_1e, as well as wearable electronic devices including display modules such as a smart glasses 10_2a, a head-mounted display 10_2b, a smart watch 10_2c, and the like, and automotive electronic devices 10_3 including display modules such as a center information display (CID), a room mirror display, and the like disposed on an instrument panel, a center fascia, or a dashboard of an automobile.

The invention should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising a display area and a non-display area adjacent to the display area;
at least one first power line in the non-display area, extending in a first direction, and connected to pixels located in the display area; and
at least one second power line extending in a second direction intersecting the first direction and adjacent to an end of the at least one first power line,
wherein the at least one first power line comprises:
a first pattern spaced apart from the at least one second power line in the first direction; and
a second pattern electrically connected to the first pattern and being relatively closer to the at least one second power line than the first pattern, and
wherein the first pattern and the second pattern comprise different respective materials.

2. The display device of claim 1, wherein the pixels have a stepped arrangement at an edge of the display area.

3. The display device of claim 1, wherein:
the first pattern comprises a metallic material, and
wherein the second pattern comprises a conductive material.

4. The display device of claim 1, wherein the at least one first power line is electrically connected to a bus line which supplies a first driving power.

5. The display device of claim 4, wherein the at least one first power line overlaps a portion of the bus line.

6. The display device of claim 4, wherein an end of the bus line is floating at an edge of the non-display area.

7. The display device of claim 4, wherein:
the at least one first power line further comprises at least one insulating layer between the first pattern and the second pattern, and
the at least one insulating layer has at least one first contact hole connecting the first pattern and the second pattern.

8. The display device of claim 7, wherein:
an end of the first pattern is connected to the second pattern via the at least one first contact hole, and
another end of the first pattern is connected to the bus line via at least one second contact hole different from the at least one first contact hole.

9. The display device of claim 8, wherein the at least one second contact hole is relatively further spaced apart from the at least one second power line than the at least one first contact hole in the first direction.

10. The display device of claim 1, further comprising at least one data line extending in the first direction and adjacent to the at least one first power line in the second direction.

11. The display device of claim 10, wherein the at least one data line comprises:
a third pattern spaced apart from the at least one second power line in the first direction; and
a fourth pattern electrically connected to the third pattern and relatively closer to the at least one second power line than the third pattern, and
wherein the third pattern and the fourth pattern comprise different respective materials.

12. The display device of claim 11, wherein:
the third pattern comprises a metallic material, and
the fourth pattern comprises a conductive material.

13. The display device of claim 11, wherein the third pattern and the fourth pattern are electrically connected via at least one third contact hole.

14. An electronic device comprising:
a processor; and
a display device which displays an image according to a control of the processor,
wherein the display device comprises:
a substrate comprising a display area and a non-display area adjacent to the display area;
at least one first power line in the non-display area, extending in a first direction, and connected to pixels located in the display area; and
at least one second power line extending in a second direction intersecting the first direction and adjacent to an end of the at least one first power line,
wherein the at least one first power line comprises:
a first pattern spaced apart from the at least one second power line in the first direction; and
a second pattern electrically connected to the first pattern and being relatively closer to the at least one second power line than the first pattern, and
wherein the first pattern and the second pattern comprise different respective materials.

15. The electronic device of claim 14, wherein the pixels have a stepped arrangement at an edge of the display area.

16. The electronic device of claim 14, wherein:
the first pattern comprises a metallic material, and
the second pattern comprises a conductive material.

17. The electronic device of claim 14, wherein the at least one first power line is electrically connected to a bus line which supplies a first driving power.

18. The electronic device of claim 17, wherein:
the at least one first power line further comprises at least one insulating layer between the first pattern and the second pattern, and
the at least one insulating layer has at least one first contact hole connecting the first pattern and the second pattern.

19. The electronic device of claim 18, wherein:
an end of the first pattern is connected to the second pattern via the at least one first contact hole, and
another end of the first pattern is connected to the bus line via at least one second contact hole different from the at least one first contact hole.

20. The electronic device of claim 19, wherein the at least one second contact hole is relatively further spaced apart from the at least one second power line than the at least one first contact hole in the first direction.
